(19) United States
(12) Patent Application Publication
(10) Pub. No.: US 2009/0195417 A1
(43) Pub. Date: Aug. 6, 2009

(54) INPUT DEVICE

(75) Inventor: Cheng-Chi CHENG, Taoyuan City (TW)

Correspondence Address: Workman Nydegger;1000 Eagle Gate Tower, 60 East South Temple, Salt Lake City, UT, 84111, US

(73) Assignee: MOBINNOVA CORP., Taoyuan City (TW)

(21) Appl. No.: 12/103,558

(22) Filed: Apr. 15, 2008

(30) Foreign Application Priority Data
Jan. 31, 2008 (TW) 097202126

(51) Int. Cl. H03M 11/00

(52) U.S. Cl. 341/22

(57) ABSTRACT

An input device applicable to a portable electronic device includes a first input interface and a second input interface. The second input interface is disposed in the center of the first input interface, such that the first input interface is divided into a first key group and a second key group. The first key group and the second key group allow the user to distinctly recognize position of each key to be pressed, and when the second input interface is operated, the user is capable of holding the gravity position of the portable electronic device by two hands, thereby stably performing the hand held operation.

### BACKGROUND OF THE INVENTION

1. Field of Invention

The present invention relates to an input device, and more particularly to an input device applicable to a portable electronic device.

2. Related Art

Business mobile phone is integrated with mobile communication function and various word processing application functions, such that business men are capable of sending and receiving the electronic mails or performing other simple word processing by using the mobile phone in addition to performing the distant communication through the mobile phone. In order to provide various word processing application functions, the business mobile phone is different from the common mobile phone that a QWERTY keyboard is disposed, so as to allow the user to input quickly.

Although the business mobile phone has larger volume than that of the common mobile phone due to the QWERTY keyboard, the business mobile phone still must accord with the light, thin, short, and small demand of the hand held electronic device, so a conflict occurs on the design of disposing the QWERTY keyboard. If it intends to make the business mobile phone light, thin, short, small, and portable, each key on the QWERTY keyboard must be small and crowded, and if it intends to make the user conveniently recognize and input, each key on the QWERTY keyboard must be big and separated by a distance. In practice, recently in most of the business mobile phones, the input convenience is sacrificed, and the QWERTY keyboard on the business mobile phone is quite crowded, such that when the user presses the keys, usually it is difficult to recognize the position of the keys to be pressed.

In order to solve the problem, for example in U.S. Pat. No. 7,113,111 and U.S. Pat. No. 7,073,964, the arrangement of the QWERTY keyboard is provided. In patent 111, a keyboard arrangement applicable to an electronic device is provided. In patent 111, the keys are divided into two regions, and the keys of the two regions are arranged with a specific angle by using a central line as the basis, so as to allow the user to easily recognize the position of each key through the inclined arrangement of the keys. Further, in patent 964, a portable device keyboard is provided. In patent 964, the keys are disposed in a staggered manner, so as to allow the user to recognize the position of each key. In the above patents, the inclined or the staggered arrangement of the keyboard realize the visual division, but all the keys are too adjacent, and the original key arrangement manner of the QWERTY keyboard is altered, the user must know the position after being inclined or staggered, so it is still inconvenient when pressing the keys.

In addition to the QWERTY keyboard, a cursor controller is further disposed on the business mobile phone. The conventional cursor controller includes a five-way key, an optical sensor, or an analogue joystick. For example, in the patent 111 or ROC Publication No. M315457, the cursor on the screen of the business mobile is controlled to move by the operation of the five-way key or the joystick. Similarly, the volume of the business mobile phone is not big, and most of the cursor controller is the analogue joystick. However, the analogue joystick is quite small and difficult to operate, and if it is disposed among the keys of the QWERTY keyboard, when the user manipulates the direction, it tends to touch the keys around the analogue joystick by mistake to cause malfunctions, so it is still an inappropriate design for the business mobile phone.

### SUMMARY OF THE INVENTION

The recent business mobile phone must have the QWERTY keyboard for matching with the simple word application processing. For the convenience of operation by the user, the conventional business mobile phone QWERTY keyboard is too crowded to be recognized in consideration of the limit of the volume, or the inclined or the staggered design is provided for the user to easily recognize, in which, however, the user must reknow the inclined or the staggered positions. In addition, the cursor controller of the conventional business mobile phone is too narrow for operation, or it tends to touch the adjacent keys by mistake to cause wrong actions, so it is not the best design of the business mobile phone. Accordingly, the present invention provides an input device of the portable electronic device, which is capable of quickly recognizing the position of each key and conveniently controlling the cursor.

The input device provided according to the present invention is applicable to a portable electronic device. The input device includes a first input interface and a second input interface. The first input interface is the QWERTY keyboard and is divided into a first key group and a second key group. The first key group and the second key group are separated by a distance. The second input interface is a touchpad and is disposed in the distance between the first key group and the second key group, such that no keys of the first key group and the second key group are adjacent, and two input manners are provided on the portable electronic device.

In the input device provided according to the present invention, the input manner of the cursor control can be provided by the touchpad of the second input interface, and the first key group and the second key group of the first input interface are separated by the second input interface, such that the first key group and the second key group are not adjacent to each other, thereby allowing the user to distinctly recognize the position of each key to be pressed. In addition, when the second input interface is operated, the user can hold the gravity position of the portable electronic device by tow hands, so as to stably perform the hand held operation.

### BRIEF DESCRIPTION OF THE DRAWINGS

The present invention will become more fully understood from the detailed description given herein below for illustration only, and thus are not limitative of the present invention, and wherein:

FIG. 1 is a schematic view of an input device according to a first embodiment of the present invention;

FIG. 2 is another schematic view of the input device according to the first embodiment of the present invention;

FIG. 3 is a schematic view of the operation state of the input device of the present invention;

FIG. 4 is a schematic view of an input device according to a second embodiment of the present invention; and

FIG. 5 is a schematic view of an input device according to a third embodiment of the present invention.

### DETAILED DESCRIPTION OF THE INVENTION

The input device provided according to the present invention provides two input modes and is applicable to a portable electronic device, in which the referred portable electronic device can be a mobile phone, a hand held PC, a media player, and other portable electronic devices capable of realizing the hand held operation. In the specific embodiments of the present invention, a business mobile phone having a QWERTY keyboard is used as the most preferred embodiment of the present invention.

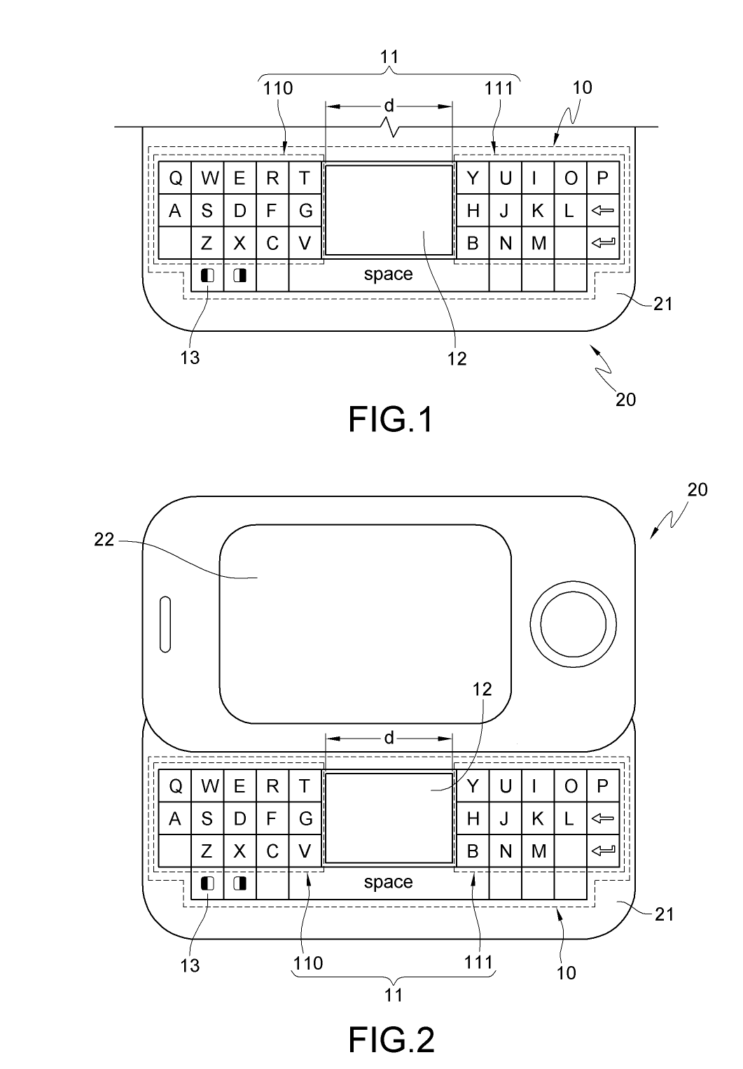

Referring to FIGS. 1 and 2, a first embodiment of the present invention is shown. The input device provided according to the present invention is applicable to a portable electronic device. A portable electronic device 20 at least includes a host 21 and a display 22, the display 22 can be directly disposed on the host 21, or can be another component connected to the host 21. In FIG. 2, the host 21 and the display 22 are two components, and the host 21 and the display 22 can relatively move, such that the host 21 and the display 22 close together, or the host 21 is moved for a distance relative to the display 22, for the convenience of using. The relative connection relationship between the host 21 and the display 22 is a known technique, so it is not described here. The The input device 10 provided according to the present invention is disposed on the host 21.

Referring to FIG. 1, the input device 10 provided according to the present invention includes a first input interface 11, a second input interface 12, and a command key set 13. The first input interface 11 is a QWERTY keyboard and includes a first key group 110 and a second key group 111. The first key group 110 and the second key group 111 are separated by a distance d, the first key group 110 at least has longitudinally arranged T, G, and V keys and laterally arranged Z and X keys, and the second key group 111 at least has longitudinally arranged Y, H, and B keys and laterally arranged M and N keys. The longitudinally arranged T, G, and V keys and the longitudinally arranged Y, H, and B keys are opposite to each other. The second input interface 12 is, for example, but not limited to, a touchpad. The touchpad is a mouse interface providing the input manner of the cursor control. The second input interface 12 is disposed between the longitudinally arranged T, G, and V keys of the first key group and the longitudinally arranged Y, H, and B keys of the second key group, such that no keys of the first key group 110 and the second key group 111 are adjacent. The command key set 13 is disposed under the first input interface 11, that is, it is adjacently under the laterally arranged Z and X keys.

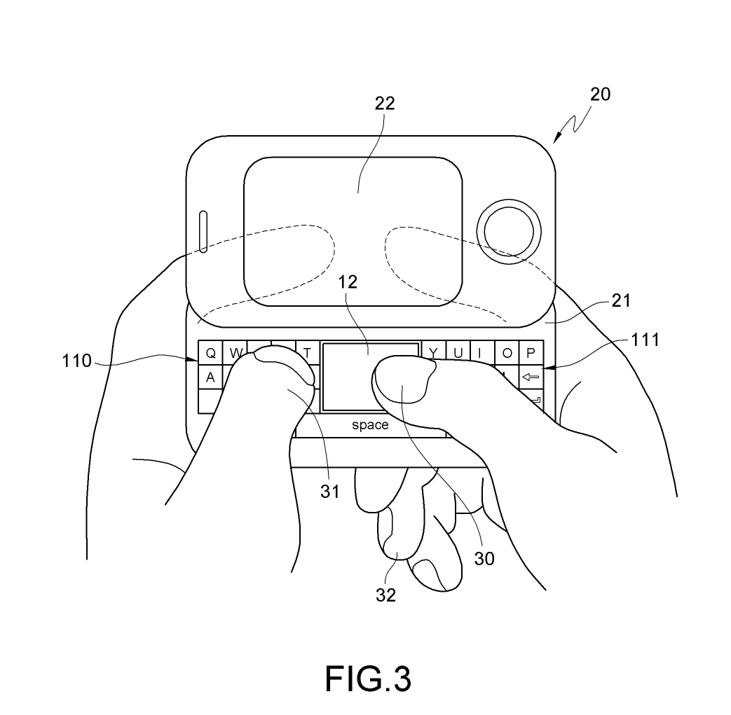

Referring to FIG. 3, the using state of the first embodiment of the present invention is shown. When the user is a right-hander, a right thumb 30 is located at the second key group 111, a left thumb 31 is located at the first key group 110, and remaining fingers 32 can be used to hold the host 21. The right thumb 30 moves on the second input interface 12 to input the instruction through the input manner of the cursor control, or presses the key to be pressed of the second key group 111. The left thumb 31 inputs the instruction through the command key set 13, or presses the key to be pressed of the first key group 110. During the action, the user only moves the left and the right thumbs 31 and 30, and the remaining fingers 32 still hold the host 21, such that when the user operates the first input interface 11 or the second input interface 12, the user's hands can can still hold the gravity position of the portable electronic device 20, and the portable electronic device 20 can stably perform the hand held operation.

Further, the first input interface 11, for example, the QWERTY keyboard, is divided into the first key group 110 and the second key group 111, so the first key group 110 and the second key group 111 respectively have the keys which are not adjacent, such that the user can distinctly know the areas where the keys are located in the region of the first key group 110 and the second key group 111. Therefore, during operation, the user can quickly recognize the key to be pressed in the first key group 110 or the second key group 111.

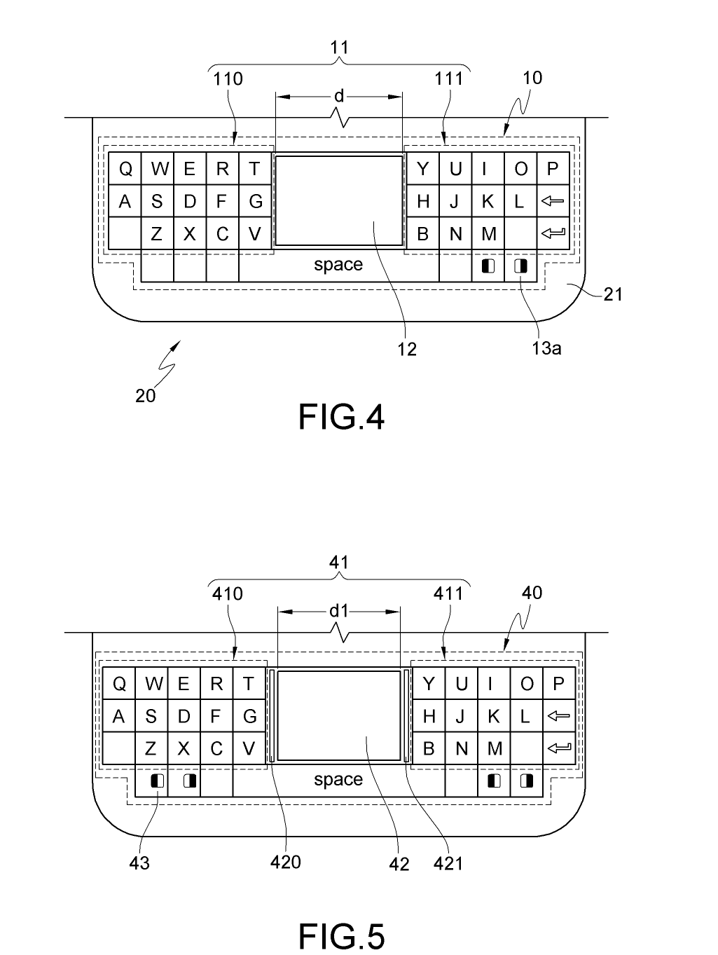

Referring to FIG. 4, a second embodiment of the input device of the present invention is shown. The arrangement manner of the first input interface and the second input interface is the same as that of the first embodiment, so the reference numerals are the same as those of the first embodiment. This embodiment matches with the left-hander users, so a command key set 13a is disposed under the second key group 111, that is, adjacently under the laterally arranged M and N keys. The operation manner of the second embodiment is similar to that of the first embodiment, except that the direction is opposite, so it is not described.

Referring to FIG. 5, a third embodiment of the input device of the present invention is shown. The input device 40 is applicable to a portable electronic device, and the portable electronic device is as described in the first embodiment, belongs to a known technique, and not described herein. The input device 40 provided by the present invention has a first input interface 41, a second input interface 42, and a pair of command key sets 43. The first input interface 41 is, for example, a QWERTY keyboard, and the first input interface 41 includes a first key group 410 and a second key group 411. The first key group 410 at least has longitudinally arranged T, G, and V keys and laterally arranged Z and X keys, and the second key group 411 at least has longitudinally arranged Y, H, and B keys and laterally arranged M and N keys. The longitudinally arranged T, G, and V keys and the longitudinally arranged Y, H, and B keys are opposite to each other. The second input interface 42 is disposed between the first key group 410 and the second key group 411, and the first key group 410 and the second key group 411 are separated by a distance d1, such that no keys of the first key group 410 and the second key group 411 are adjacent. For example, the second input interface 42 is, but not limited to, a touchpad, and is a mouse interface. A first sensor 420 and a second sensor 421 are disposed at two sides of the second input interface 42 respectively, the first sensor 420 is adjacent to the longitudinally arranged T, G, and V keys of the first key group 410, and the second sensor 421 is adjacent to the longitudinally arranged Y, H, and B keys of the second key group 411. The command key sets 43 are correspondingly disposed under the first key group 410 and the second key group 411, that is, adjacently under the laterally arranged Z and X keys and adjacently under the laterally arranged M and N keys. When the first sensor 420 senses the action of the left thumb on the second input interface 42, a valid command is generated to the command key set 43 adjacently under the laterally arranged M and N keys, and an invalid command is generated to the command key set 43 adjacently under the laterally arranged Z and X keys. When the second sensor 421 senses the action of the right thumb on the second input interface 42, the valid command is generated to the command key set 43 adjacently under the laterally arranged Z and X keys, and the invalid command is generated to the command key set 43 adjacently under the laterally arranged M and N keys.

When the user is a right-hander, the second sensor 421 senses the action of the right thumb on the second input interface 42, and the valid command is generated to the command key set 43 adjacently under the laterally arranged Z and X keys, and the invalid command is generated to the command key set 43 adjacently under the laterally arranged M and N keys, such that the left thumb can input instructions through the command key set 43 receiving the valid command.

When the user is a left-hander, the first sensor 420 senses the action of the left thumb on the second input interface 42, and the valid command is generated to the command command key set 43 adjacently under the laterally arranged M and N keys, and the invalid command is generated to the command key set 43 adjacently under the laterally arranged Z and X keys, such that the right thumb can input instructions through the command key set 43 receiving the valid command.

To sum up, the first input interface is divided by the second input interface into the first key group and the second key group, which are separated by a distance and are not adjacent to each other. The first key group and the second key group respectively have the keys, such that the user can distinctly and quickly recognize the position of each key. Further, when the second input interface or the first input interface is operated, the gravity of the portable electronic device is held by two hands of the user, so as to stably perform the hand held operation on the portable electronic device.

What is claimed is:

1. An input device, applicable to a portable electronic device, comprising:
a first input interface, comprising a first key group and a second key group which are separated by a distance and are not adjacent to each other; and
a second input interface, disposed between the first key group and the second key group.

2. The input device as claimed in claim 1, wherein the first input interface is a QWERTY keyboard, and the second input interface is a touchpad.

3. The input device as claimed in claim 2, wherein the touchpad is located between longitudinally arranged T, G, and V keys of the first key group and longitudinally arranged Y, H, and B keys of the second key group of the first input interface.

4. The input device as claimed in claim 1, wherein a command key set is disposed under the first key group.

5. The input device as claimed in claim 1, wherein a command key set is disposed under the second key group.

6. An input device, applicable to a portable electronic device, comprising:
a first input interface, comprising a first key group and a second key group which are separated by a distance and are not adjacent to each other;
a second input interface, disposed between the first key group and the second key group, and having a first sensor and a second sensor on two sides; and
a pair of command key sets, correspondingly disposed under the first key group and the second key group, for generating a valid command or an invalid command according to a signal of the first sensor or the second sensor.

7. The input device as claimed in claim 6, wherein the first input interface is a QWERTY keyboard, and the second input interface is a touchpad.

8. The input device as claimed in claim 7, wherein the touchpad is located between longitudinally arranged T, G, and V keys of the first key group and longitudinally arranged Y, H, and B keys of the second key group of the first input interface.

9. The input device as claimed in claim 7, wherein the pair of command key set is adjacently under the laterally arranged Z and X keys and adjacently under the laterally arranged M and N keys.
